(19) United States
(12) Patent Application Publication
(10) Pub. No.: US 2026/0229837 A1
(43) Pub. Date: Aug. 6, 2026

(54) ULTRAVIOLET LASER DIODE ON A NANO-POROUS ALUMINUM GALLIUM NITRIDE TEMPLATE

(71) Applicant: The Regents of the University of California, Oakland, CA (US)

(72) Inventors: Yifan Yao, Goleta, CA (US); Matthew S. Wong, Santa Barbara, CA (US); Michael Iza, Goleta, CA (US); Shuji Nakamura, Santa Barbara, CA (US); Steven P. DenBaars, Goleta, CA (US)

(73) Assignee: The Regents of the University of California, Oakland, CA (US)

(21) Appl. No.: 19/119,171

(22) PCT Filed: Nov. 3, 2023
(86) PCT No.: PCT/US2023/078595

§ 371 Date: Apr. 8, 2025

Related U.S. Application Data
(60) Provisional application No. 63/422,161, filed on Nov. 3, 2022.

(51) Int. Cl. H01S 5/02; H01S 5/343

(52) U.S. Cl. CPC H01S 5/0211; H01S 5/34333

(57) ABSTRACT

A III-nitride laser diode with an emission wavelength between 300 nin and 370 nm grown on or above a nano-porous AlₐGa₁₋ₐN (0<a≤1) layer, which is grown on or above a GaN substrate.

### CROSS REFERENCE TO RELATED APPLICATION

This application claims the benefit under 35 U.S.C. Section 119(e) of the following co-pending and commonly-assigned application:

U.S. Provisional Application Ser. No. 63/422,161, filed on Nov. 3, 2022, by Yifan Yao, Matthew S. Wong, Michael Iza, Shuji Nakamura and Steven P. DenBaars, entitled “ULTRAVIOLET LASER DIODE ON A NANO-POROUS ALUMINUM GALLIUM NITRIDE TEMPLATE,” attorneys' docket number G&C 30794.0831USP1 (UC 2023-870-1);
which application is incorporated by reference herein.

### STATEMENT REGARDING FEDERALLY SPONSORED RESEARCH AND DEVELOPMENT

This invention was made with Government support under Grant No. W911NF-22-1-0210 awarded by the Defense Advanced Research Projects Agency (DARPA). The Government has certain rights in this invention.

### BACKGROUND OF THE INVENTION

### 1. Field of the Invention

The present invention is related to a method of fabricating an ultraviolet (UV) light-emitting III-nitride laser diode (LD) with an emission wavelength between 300 nm and 370 nm fabricated on a nano-porous aluminum gallium nitride (AlGaN) template.

### 2. Description of the Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

Efficient AlGaN-based LDs with an emission wavelength between 300 nm and 370 nm have numerous applications in the field of lithography, curing, chemical sensing, medical treatment, and cytometry etc. This wavelength range is usually referred as a UV-A wavelength (including some parts of UV-B).

The active region of the LD where light is generated for this wavelength range is usually composed of AlₓGa₁₋ₓN with an Al composition x ranging from about 0 to 0.5. To efficiently confine the light and reduce the optical loss to achieve lasing operation, the AlGaN layers on, above, below, or under the active region, which are often referred as waveguiding layers, separate confinement heterostructure (SCH) layers, and/or cladding layers, need to be optically transparent to the laser wavelength, and the cladding layers have to provide enough refractive index contrast with respect to the active region and waveguiding or SCH layers. In addition, waveguiding or SCH layers also have to have enough band offset between the waveguiding or SCH layers and the active region to confine the carriers within the active region. This also necessitates the Al composition, y, in the thick Al_{y}Ga_{1-y}N cladding layers being greater than x (y>x), so that the cladding layers have a bandgap energy higher than the energy of the photons emitted from the active region, and the cladding layers have a refractive index less than that of the active region and the waveguiding or SCH layers. In practical terms, the highest Al composition, y, in the waveguiding layers is higher than the Al composition, x, in the active region by at least 10% (y>=x+0.1) to effectively confine the carriers within the active region.

Current state-of-the-art LDs have been formed on low-dislocation-density GaN substrates grown by Hydride Vapor Phase Epitaxy (HVPE) to reduce the dislocation density (less than 5×10⁶ cm⁻²) to develop LDs with a lifetime longer than 10,000 hours. This is illustrated in FIG. 1, which is a graph of Laser Lifetime (hours) vs. Dislocation density in Epi-layer (cm⁻²) for blue light-emitting (405 nm) LDs, including LDs grown using an SEI (Sumitomo Electric Industries) GaN substrate, a GaN substrate plus ELOG (Epitaxial Lateral OverGrowth), a Sapphire substrate plus ELOG, and direct growth on a Sapphire substrate. As noted, reliable LDs with a lifetime >10000 hours should be formed on a GaN substrate, because the GaN substrate has a dislocation density of less than 1×10⁶ cm⁻². [1] [2]

However, there are several growth challenges when growing a UV-A LD on a GaN substrate, because the waveguide and cladding layers have to be AlGaN layers for emission wavelengths of 300 nm to 370 nm, as mentioned above. Since AlGaN has a smaller lattice parameter than the underlying GaN substrate, there is an unavoidably large tensile stress due to the lattice mismatch during the material growth. Extended defects, such as cracking, that are catastrophic to device operation are usually formed during the growth to relieve the stress. In fact, there are certain limitations on the AlGaN thickness (called “critical thickness”) related to the Al composition before plastic deformation (cracking) can occur, which was studied extensively through experiments and theory. [3] Certain techniques must be employed to alleviate such growth stress when growing thicker, higher Al content, cladding and waveguiding layers in an AlGaN LD on a GaN substrate. These include, but are not limited to, ELOG over a Silicon Dioxide (SiO₂) mask layer, regrowth on a patterned AlGaN template, etc. Due to these cracking problems of AlGaN layers grown on a GaN substrate, no UV-A LDs on GaN substrates have been demonstrated with a reliable lifetime.

In another example, a UV-A LD can be grown on an AlN substrate or AlN template grown on a Sapphire substrate to prevent cracking problems, which will necessarily have compressive stress due to the lattice mismatch. However, AlN substrates are currently too expensive to use commercially. Due to the compressive strain, cracking can be prevented when the AlGaN LD is grown on AlN. Therefore, the most popular method to grow a UV-A LD has been an AlN template grown on a Sapphire substrate. However, because of the large lattice mismatch between the AlN template and the AlGaN active region when the emission wavelength of the LD is about 355 nm to 375 nm, a large number of dislocations are formed.

FIG. 2 is a cross sectional schematic of a conventional LD epitaxial structure with an emission wavelength of about 355 nm, where an AlN template on a Sapphire substrate is used with an ELOG process to fabricate an LD structure while preventing cracking. [4] The LD 200 is comprised of a Sapphire (0001) substrate 201, with the following layers deposited successively in the following order on the substrate 201: an AlN layer 202, an Al_{0.25}Ga_{0.75}N layer 203, an n-Al_{0.2}Ga_{0.8}N cladding layer 204, an n-Al_{0.1}Ga_{0.9}N waveguiding layer 205, a light-emitting active region comprised of GaN/AlGaN multiple quantum wells (MQWs) 206, a p-Al_{0.1}Ga_{0.9}N waveguiding layer 207, a p-AlGaN electron blocking layer (EBL) 208, a p-Al_{0.2}Ga_{0.8}N cladding layer 209, and p-GaN contact layer 210.

When an AlN template is grown on a Sapphire substrate, there is a large number of dislocations (e.g., a dislocation density >5×10⁷ cm⁻²) due to a large lattice mismatch (<15%) between the Sapphire substrate and the AlN template. For example, FIG. 3, which is a graph of TDD (threading dislocation density) (cm⁻²) vs. Year, chronicles the state-of-the-art development of AlN templates formed on Sapphire substrates, showing no demonstrations of TDD below 10⁷ cm⁻².

To reduce the dislocation density, ELOG is performed. After the ELOG, the dislocation density in the AlGaN template is still greater than 2×10⁸ cm⁻², as shown in FIG. 4, which is a cross-sectional TEM (transmission electron microscopy) image of a conventional AlGaN layer on an AlN template with a dislocation density higher than 2×10⁸ cm⁻² after the ELOG process. [4]

Due to the high dislocation density of an AlN template grown on a Sapphire substrate, LDs with an emission wavelength from 355 nm to 375 nm have never been commercialized. As mentioned above, another problem with LDs in this wavelength range is that the lattice mismatch between an AlN template and the AlGaN layers of the LD structure, especially with an emission wavelength >350 nm, form more dislocations at the interface between the AlN template and the AlGaN layers of the LD structure. These dislocations degrade device performance.

### SUMMARY OF THE INVENTION

The present invention discloses a UV-A LD that uses a waveguiding or SCH layer formed on a nano-porous n-AlGaN layer as a cladding layer in order to circumvent the growth challenges described above. Nano-porous AlGaN has a much lower refractive index than that of a non-porous AlGaN layer with the same Al composition of AlGaN. Therefore, the condition to grow a thick, much higher Al composition, Al_{y}GaₓN cladding layer where the Al composition, y, needs to be higher than the Al composition, x, of AlₓGa₁₋ₓN in the active region is not necessary and similar optical confinement can be achieved with a thinner, lower Al content, Al₂Ga_{1-z}N layer (z<y), which is easier to form on a GaN substrate without cracking defects. Thus, a GaN substrate with a dislocation density less than 1×10⁶ cm⁻² could be used without cracking defects. In addition, the Al composition of a nano-porous n-AlGaN cladding layer of an LD structure is lower than that of a conventional structure. This minimizes the strain to prevent cracking defects and also minimizes the generation of new dislocation defects at the interface between the LD structure and the nano-porous n-AlGaN cladding layer.

A p-AlGaN cladding layer needs to have a relatively higher Al composition when not nano-porous for good mode confinement, which again introduces many growth challenges, as describe above. Instead, transparent oxide (TO) materials could be used as the p-cladding layer to minimize the strain. The TO could be deposited on a p-waveguide or thin p-AlGaN cladding layer with a thickness of about 0 nm to 300 nm. Thus, it is preferable that the n-AlGaN cladding layer should be nano-porous AlGaN to minimize the Al composition, and the cladding layer should be a TO or a TO+thin p-AlGaN cladding layer with a thickness of about 0 nm to 300 nm.

When the TO has a high conductivity, such as indium tin oxide (ITO) or gallium oxide (Ga₂O₃), a p-contact could be made on the TO. When the conductivity of the TO is not high enough, the p-contact could be made on the p-type waveguide. Since the TO can only be n-type, the p-contact on the TO will create a tunnel junction (TJ) contact.

Thus, the present invention should provide a superior structure and method to fabricate a UV-A LD on a GaN substrate with a dislocation density less than 1×10⁶ cm⁻² and the UV-A LD with a lifetime of more than 10,000 hours.

### BRIEF DESCRIPTION OF THE DRAWINGS

Referring now to the drawings in which like reference numbers represent corresponding parts throughout:

FIG. 1 is the LD lifetime in hours versus dislocation density in epi-layer, which shows that a reliable LD with a lifetime >10000 hours should be formed on a GaN substrate.

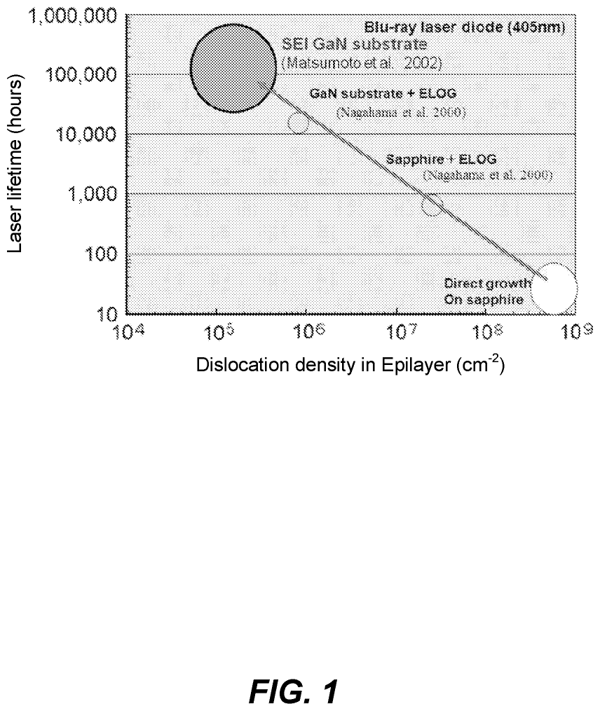

FIG. 2 is a cross sectional schematic of a conventional LD epitaxial structure comprised of a UV-A LD on an AlN template on a Sapphire substrate fabricated using an ELOG process.

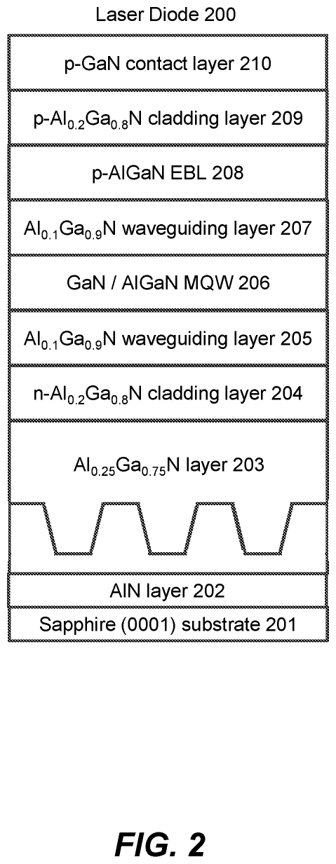

FIG. 3 is a chronicle of the state-of-the-art of AlN templates formed on Sapphire substrates showing no demonstration of TDD below 10⁷ cm⁻².

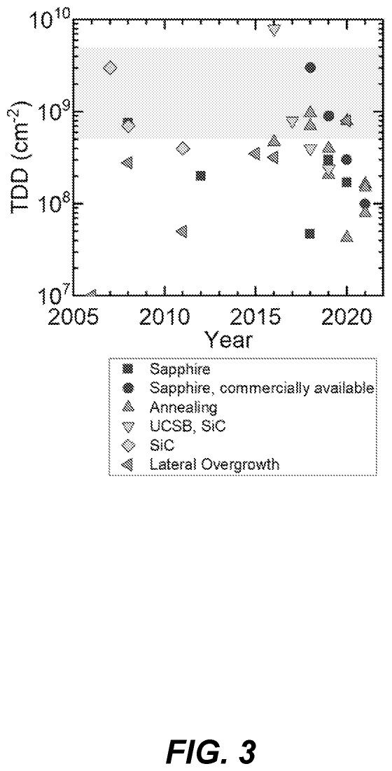

FIG. 4 is a cross-sectional TEM image of a conventional AlGaN layer on an AlN template with a dislocation density higher than 2×10⁸ cm⁻² after an ELOG process.

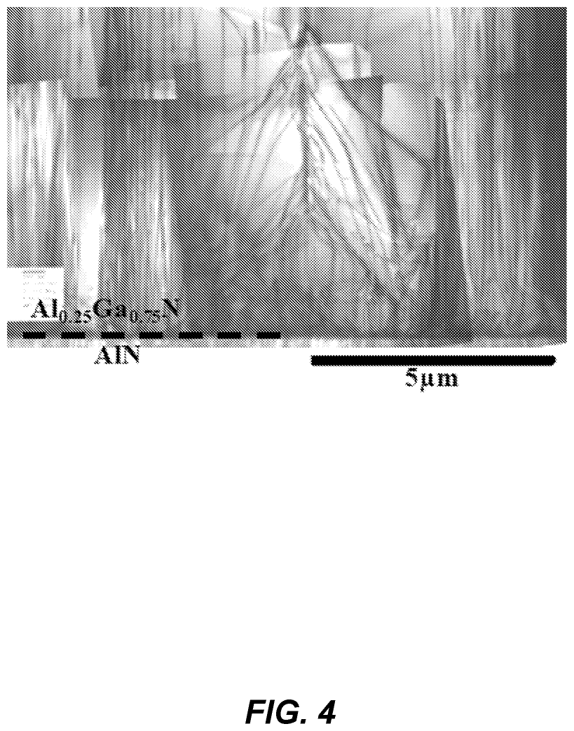

FIG. 5 is a cross sectional schematic of an LD epitaxial structure with an SCH structure formed on a nano-porous AlGaN layer on a GaN substrate.

FIG. 6 is a cross sectional schematic of an LD epitaxial structure with an SCH structure formed on a nano-porous AlGaN layer on a GaN substrate with a p-type short-period superlattice (SPSL) structure in the p-cladding layer.

FIG. 7 is a cross sectional schematic of an LD diode epitaxial structure with a SCH structure formed on a nano-porous AlGaN layer on a GaN substrate with a continuously-graded AlGaN structure in the p-cladding layer.

FIG. 8 is a mode simulation solution using Ansys Lumerical MODE Optical Waveguide & Coupler Solver™ of a UV LD formed on a nano-porous AlGaN layer as an n-cladding layer template and with an oxide layer above the LD showing enhanced mode confinement performance.

FIG. 9 is a flowchart illustrating an example process for fabricating an epitaxial device structure according to the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized, and structural changes may be made without departing from the scope of the present invention.

### Overview

The present invention describes UV LDs formed on a nano-porous AlGaN layer. The UV LDs have emission wavelengths between 300 nm and 370 nm, with a light-emitting active region composed of AlₓGa₁₋ₓN, where x is greater than or equal to 0 and x is less than or equal to 0.5. UV LDs have been demonstrated on GaN substrates before, but still face many challenges with device reliability and growth difficulties as mentioned above.

By employing UV LDs with a nano-porous AlGaN layer as an n-type cladding layer, the limitations of the prior art can be overcome. Nano-porous AlGaN layers can be formed by electro-chemically etching an n-AlGaN template in an acidic solution. The n-AlGaN template is deposited on a GaN substrate using either MOCVD or MBE, and has an n-type dopant concentration of an Si or Ge dopant in the range of 10¹⁷ to 10²⁰ cm⁻³. By applying a voltage across the n-AlGaN template in the acidic solution, part of the n-AlGaN template can be removed, resulting in a nano-porous AlₐGa₁₋ₐN layer.

A refractive index of a nano-porous III-nitride layer can be calculated by averaging the refractive index of air (nₐᵢᵣ=1) and that of a non-porosified III-nitride layer based on the volume of the pores. Depending on the level of porosity, much better light confinement can be achieved from the lower refractive index of a porosified III-nitride layer as compared with a non-porosified III-nitride layer. Another advantage of a nano-porous III-nitride layer is that residual strain in the as-grown III-nitride layer can be relaxed after the porosification process, which helps to manage the tensile stress accompanied when growing AlGaN layers on a GaN substrate.

The Al composition, a, in the nano-porous AlₐGa₁₋ₐN layer is higher than the Al composition, x, in an AlₓGa₁₋ₓN active region containing at least one quantum well grown on or above the nano-porous AlₐGa₁₋ₐN layer, where 0<a≤1, 0<x≤1 and a>x, so that the bandgap energy of the nano-porous AlₐGa₁₋ₐN layer is higher than a photon energy of the emission wavelength of the active region and LD, and hence the nano-porous AlₐGa₁₋ₐN layer becomes transparent to the emitted wavelength.

The rest of the LD structure can be regrown epitaxially on the nano-porous AlₐGa₁₋ₐN layer. The LD structure has a SCH (or waveguiding) layer to confine the carriers into the active region. The active region is on or above an n-SCH (or waveguiding) layer, and under or below a p-SCH (or waveguiding) layer.

The n-SCH layer is an n-type Al_{b}Ga_{1-b}N layer grown on or above the nano-porous AlₐGa₁₋ₐN layer, before the AlₓGa₁₋ₓN active region is grown, where 0<b≤1, b>a, and b>x, wherein the n-type Al_{b}Ga_{1-b}N layer comprises an SCH layer or waveguiding layer. The n-type Al_{b}Ga_{1-b}N layer has an in-plane lattice constant or strain that is at least 5% relaxed.

The p-SCH layer is a p-type Al_{c}Ga_{1-c}N layer grown on or above the AlₓGa₁₋ₓN active region, where 0<c≤1 and c>x, wherein the p-type Al_{c}Ga_{1-c}N layer comprises an SCH layer or waveguiding layer. The p-type Al_{c}Ga_{1-c}N layer has an Mg dopant concentration in a range from 10¹⁷ cm⁻³ to 10²⁰ cm⁻³. The p-type Al_{c}Ga_{1-c}N layer has a bandgap energy equal to a photon energy of the emission wavelength of the III-nitride-based light emitting active region.

The p-type Al_{c}Ga_{1-c}N layer may contain at least one superlattice having at least two alternating layers of AlₓGa₁₋ₓN and Al_{y}Ga_{1-y}N where 0<x≤1 and 0<y≤1. The p-type Al_{c}Ga_{1-c}N layer may be three-dimensional (3D) polarization doped, having a continuously varying composition between the at least two alternating layers of AlₓGa₁₋ₓN and Al_{y}Ga_{1-y}N.

In addition, n-cladding and/or p-cladding layers having a refractive index less than that of the SCH (or waveguiding) layers may be used to confine the light within the SCH (waveguiding) layers and the active region.

The n-type cladding layer is formed on or above the nano-porous AlₐGa₁₋ₐN layer, before the n-SCH layer is deposited.

The p-type cladding layer is formed on or above the p-SCH layer and is a p-Al_{d}Ga_{1-d}N cladding layer, where 0<d≤1, having an average Al composition that is greater than or equal to the p-type Al_{c}Ga_{1-c}N layer, where d>c or d=c. The p-Al_{d}Ga_{1-d}N cladding layer may also comprise a compositionally graded structure, where d varies from d1 to d2 and d1 is greater than d2. In the case of the compositionally graded structure, the p-type cladding layer can be doped or unintentionally doped.

The p-type cladding layer has a thickness between 0 to 300 nm, and has a refractive index less than the p-type Al_{c}Ga_{1-c}N layer and the active region. The p-type cladding layer can contain one or more SPSL structures, where an effective Mg activation energy is reduced by a polarization field.

An oxide layer is deposited on or above or the p-SCH layer and/or the p-cladding layer because the refractive index of the oxide layer is less than that of the p-SCH layer. The oxide layer can be fully or partially transparent to the emission wavelength of the LD. The oxide layer can preferable cover more than 50% of the area of the p-SCH layer. The oxide layer should be comprised of oxide materials with a refractive index lower than that of the p-SCH layer, such as indium tin oxide (ITO), zinc oxide (ZnO), gallium oxide (GaOₓ), indium zinc oxide (IZO), silicon diode (SiO₂) or another oxide layer.

A p-contact layer is deposited on the oxide layer, or the p-SCH layer when the conductivity of the oxide layer as the p-cladding layer is not high enough to make a good ohmic contact. When the conductivity (n-type conductivity) of the oxide layer is low enough to make the good ohmic contact, the p-contact should be made onto the oxide layer.

An n-type contact is deposited on one or more of the n-type layers, such as the nano-porous n-AlₐGa₁₋ₐN layer or the n-Al_{b}Ga_{1-b}N layer.

The present invention also discloses devices using the above-described structures.

### EMBODIMENTS

### First Embodiment

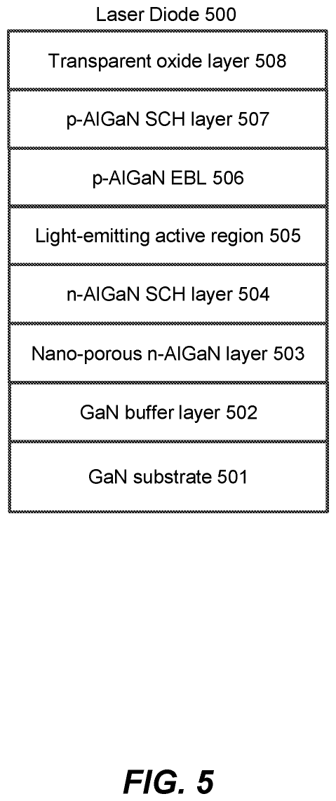

The UV LD on a nano-porous AlGaN layer on a GaN substrate according to a first embodiment is shown in FIG. 5, which is a cross sectional schematics of an LD epitaxial structure formed on the nano-porous AlGaN layer on the GaN substrate. The LD 500 is comprised of a commercially available GaN substrate 501, with the following layers deposited successively in the following order on the substrate 501: a GaN buffer layer 502, an Si-doped AlGaN template which can be electro-chemically etched into a nano-porous n-AlGaN layer 503, an n-AlGaN SCH layer 504, a light-emitting active region 505, a p-AlGaN EBL 506, a p-AlGaN SCH layer 507, and a fully or partially transparent oxide layer 508.

As noted above, the GaN buffer layer 502 can have a thickness between 0 nm to 2000 nm and is deposited epitaxially on the commercially available GaN substrate 501. The GaN buffer layer 502 can be UID (unintentionally doped) or lightly n-type.

The subsequently deposited Si-doped AlGaN template can have a dopant concentration in the range of 10¹⁷ to 10²⁰ cm⁻³, and preferably higher than 10¹⁸ cm⁻³. This template can have a thickness between 100 nm to 2000 nm, and can be porosified into the nano-porous n-AlGaN layer 503 as an n-type cladding layer for the LD 500.

The LD 500 also contains an n-AlGaN SCH layer 504 below or under the light-emitting active region 505, and a p-AlGaN SCH layer 507 on or above the light-emitting active region 505, where the thickness of layers 504, 507 ranges from 20 nm to 200 nm. The n-AlGaN SCH layer 504 can be UID or Si-doped at an average concentration below 10¹⁹ cm⁻³, and preferably one order of magnitude lower than the doping concentration in the nano-porous n-AlGaN layer 503.

The light-emitting active region 505 contains at least one quantum well structure and is composed of AlₓGa₁₋ₓN, where 0<x≤1, and preferably x<0.3. The emission wavelength of the LD 500 can range from 300 nm to 370 nm, and preferably above 330 nm.

The bandgap energy of the n-AlGaN SCH layer 504 and the p-AlGaN SCH layer 507 should be higher than the photon energy of the emitted light of the LD 500 to confine the carriers of electrons and holes within the active region 505. The Al composition, a, in the nano-porous n-AlₐGa₁₋ₐN layer 503 should be greater than the Al composition, x, in the AlₓGa₁₋ₓN active region 505, or a>x. The p-AlGaN EBL 506 can be UID or Mg-doped, and has a thickness ranging from 0 nm to 20 nm, and has a higher Al composition than the p-AlGaN SCH layer 507. The fully or partially transparent oxide layer 508 is deposited on or above the p-AlGaN SCH layer 507 through common vacuum deposition techniques, and can have thickness between 100 nm to 500 nm.

### Second Embodiment

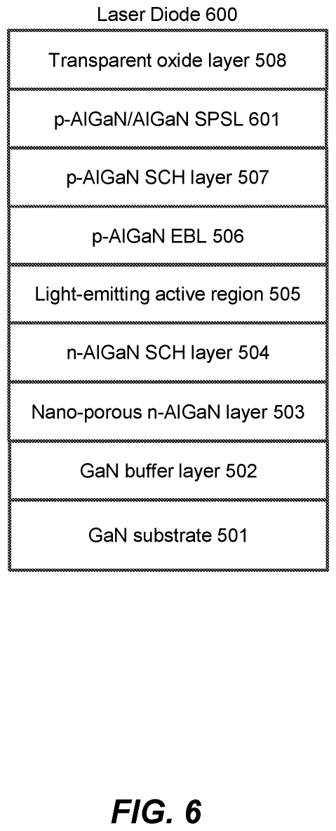

The UV LD on a nano-porous AlGaN layer on a GaN substrate according to a second embodiment is shown in FIG. 6, which is a cross-sectional schematic of an LD epitaxial structure with an SCH structure formed on the nano-porous AlGaN layer on the GaN substrate with an SPSL structure in a p-cladding layer. The LD 600 of this second embodiment has the same structure as the LD 500 of the first embodiment, except that it also includes a p-type III-nitride layer comprising a p-AlGaN/AlGaN SPSL structure 601 on or above the p-AlGaN SCH layer 507. The p-AlGaN/AlGaN

SPSL structure 601 is comprised of alternating AlₘGa₁₋ₘN and AlₙGa₁₋ₙN layers, where m≠n, and preferably the difference in Al compositions m and n is greater than or equal to 0.2. The alternating AlₘGa₁₋ₘN and AlₙGa₁₋ₙN layers may be doped by Mg and have a dopant concentration in the range of 10¹⁷ to 10²¹ cm³. The thickness of the alternating AlₘGa₁₋ₘN and AlₙGa₁₋ₙN layers may be below 10 nm, or more preferably below 3 nm. The total thickness of the p-AlGaN/AlGaN SPSL structure 601 can be between 10 nm to 150 nm, and more preferably below 50 nm.

### Third Embodiment

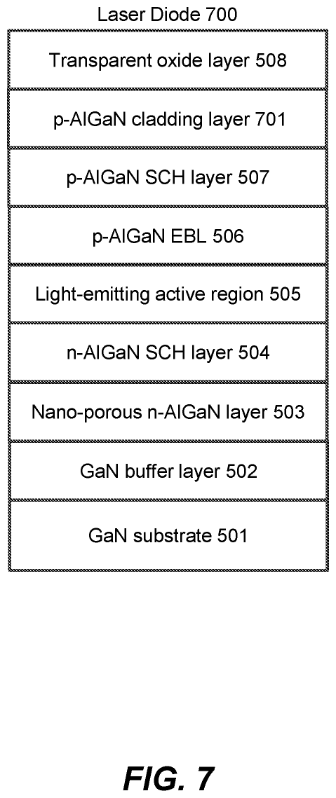

The UV LD on a nano-porous AlGaN layer on a GaN substrate according to a third embodiment, as shown in FIG. 7, which is a cross-sectional schematic of an LD epitaxial structure with an SCH structure formed on the nano-porous AlGaN layer on the GaN substrate with a continuously graded AlGaN structure in a p-cladding layer. The LD 700 of this third embodiment has the same structure as the LD 500 of the first embodiment, except that it also includes a p-AlGaN cladding layer 701 comprised of a three-dimensional (3D) polarization-enhanced doping structure on or above the p-AlGaN SCH layer 507. The 3D polarization-enhanced doping structure of the p-AlGaN cladding layer 701 comprises AlₖGa₁₋ₖN, where 0<k≤1, with a thickness between 40 nm to 400 nm. The composition value k of the AlₖGa₁₋ₖN is continuously varied along the growth direction. The composition profile depends on the polarity of the substrate 501. In the case of a c-plane GaN substrate 501, the composition value k in the AlₖGa₁₋ₖN is continuously decreasing along the growth direction. The AlₖGa₁₋ₖN layer may also be UID or doped with Mg at an average concentration between 10¹⁷ to 10²¹ cm⁻³.

### ADVANTAGES AND IMPROVEMENTS

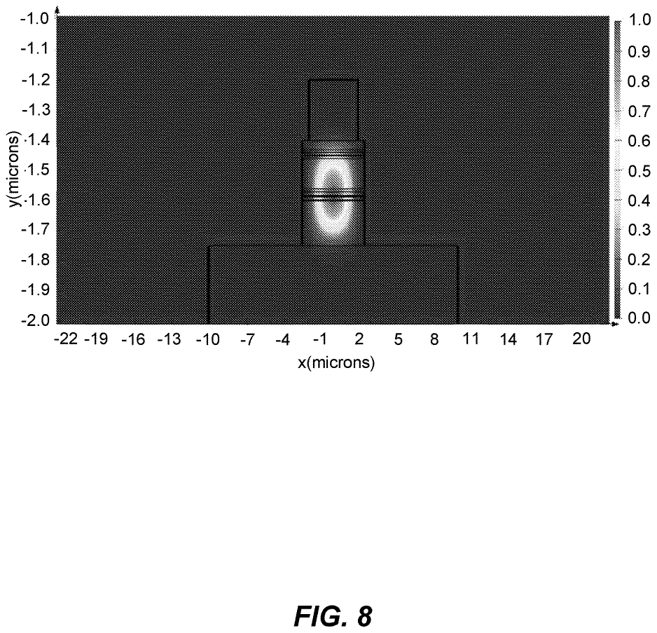

FIG. 8 shows a mode simulation solution using Ansys Lumerical MODE Optical Waveguide & Coupler Solver of a typical UV-A LD formed on a nano-porous AlGaN templates with an oxide layer above the LD, according to the present invention.

The active region is comprised of three periods of 3 nm GaN quantum wells (QWs) and 10 nm Al_{0.15}Ga_{0.85}N quantum barriers (QBs), and has an emission wavelength of about 360 nm. The Al compositions of the nano-porous AlGaN layer (assuming 30% porosity), n-SCH layer, and p-SCH layer, is set to be about 10%. The thicknesses of the nano-porous AlGaN layer, n-SCH layer, and p-SCH layer, is about 1000 nm, 150 nm and 100 nm, respectively. The p-cladding layer comprises a thin AlGaN layer, with a thickness of about 50 nm, and with its composition graded from 20% to 0%, upon which is deposited a 200 nm ITO layer.

Enhanced mode confinement can be achieved with the structure disclosed by this invention. The mode area is centered around the light emitting active region and well confined in the active region and SCH regions with small modal area of 0.92 μm². The light confinement factor for this structure is about 1.7% per QW.

Another mode simulation was attempted with the exact same structure without the nano-porous AlGaN layer and the oxide layer. In this simulation, the nano-porous AlGaN layer is replaced by an as-grown AlGaN layer with the same Al composition. The oxide layer is replaced by a typical Pt/Au p-contact on GaN. No mode solution can be solved in such a structure (not shown). This comparison demonstrates that a structure disclosed by the present invention is superior to a conventional structure typical for laser diodes at this wavelength with better light confinement.

### Process Steps for Fabrication

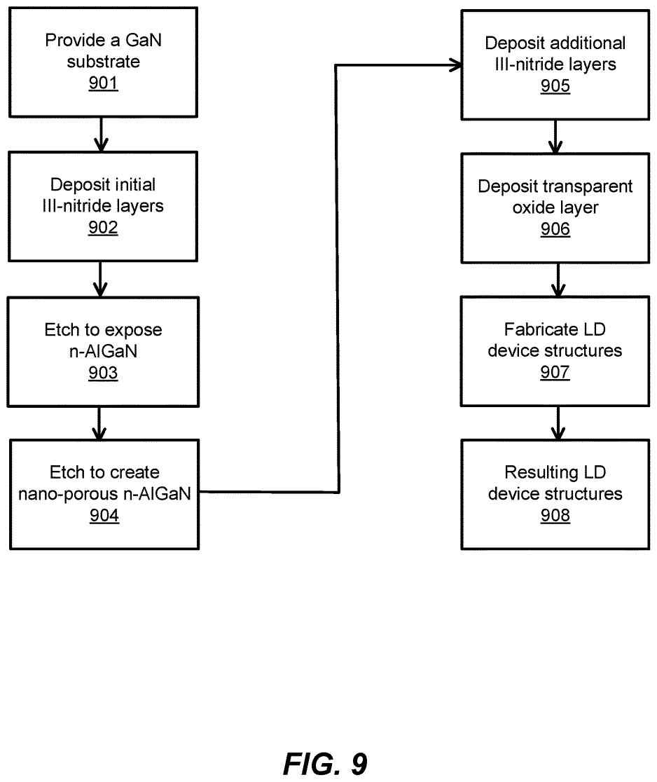

FIG. 9 is a flowchart illustrating an example process 900 for fabricating a device, comprising: a III-nitride laser diode with an emission wavelength between 300 nm and 370 nm, grown on or above a nano-porous AlₐGa₁₋ₐN layer, where 0<a≤1, and the nano-porous AlₐGa₁₋ₐN layer is grown on or above a III-nitride substrate.

Block 901 represents the step of providing the GaN substrate 501.

Block 902 represents the steps of successively depositing initial III-nitride layers, using MOCVD or MBE, in the following order, the GaN buffer layer 502, the n-AlₐGa₁₋ₐN layer 503, and the n-AlGaN SCH (or waveguiding) layer 504.

Block 903 represents the step of etching to expose the n-AlₐGa₁₋ₐN layer 503. The III-nitride layers of the LD epitaxial structure can be etched using common etching techniques, including reactive ion etching (RIE) or inductive Inductively Coupled Plasma RIE Etching (ICP), to expose the n-AlₐGa₁₋ₐN layer 503.

Block 904 represents the step of etching to create the nano-porous n-AlₐGa₁₋ₐN layer 503. This step includes depositing one or more electrical contacts on top of the n-AlGaN SCH layer 504 or on the exposed n-AlₐGa₁₋ₐN layer 503; immersing the epitaxial structure, and specifically the exposed n-AlₐGa₁₋ₐN layer 503, into an acidic solution, preferably, in an oxalic acid solution with its molar concentration ranging from 0.1M to 1M, preferably at 0.3M; and applying a voltage bias between the electrical contacts on top of the n-AlGaN SCH layer 504 or on the exposed n-AlₐGa₁₋ₐN layer 503, and the solution, to electro-chemically etch the exposed n-AlₐGa₁₋ₐN layer 503 in order to create a nano-porous morphology, which results in the nano-porous n-AlₐGa₁₋ₐN layer 503. The porosity (volume/size of pores) can vary with the applied voltage bias and etching duration. A number of references can be found on the nano-porous III-nitride morphology formed by electro-chemical etching. [5]

After forming the nano-porous n-AlₐGa₁₋ₐN layer 503 as a template, Block 905 represents the steps of depositing additional III-nitride layers, using MOCVD or MBE, on the nano-porous n-AlₐGa₁₋ₐN layer 503, including the n-AlGaN SCH (or waveguiding) layer 504, light-emitting active region 505, EBL layer 506, p-AlGaN SCH (or waveguiding) layer 507, to form the LD 500, 600, 700, with an SCH structure. These steps optionally include the steps of depositing a p-type III-nitride layer comprising a p-AlGaN/AlGaN SPSL structure 601 on or above the p-AlGaN SCH layer 507, and/or a p-AlGaN cladding layer 701 comprised of a three-dimensional (3D) polarization-enhanced doping structure on or above the p-AlGaN SCH layer 507.

Block 906 represents the step of depositing an oxide layer 508 on the additional III-nitride layers, using common vacuum deposition techniques, such as electron beam evaporation (e-beam), thermal evaporation, sputter, ion beam deposition (IBD), plasma enhanced chemical vapor deposition (PECVD), atomic layer deposition (ALD), etc.

Block 907 represents the step of fabricating the result epitaxial structure into the LD 500, 600, 700, using common semiconductor processing techniques. The ridge (mesa) structure of the LD 500, 600, 700 is defined using semiconductor lithography techniques and formed using semiconductor dry etching techniques, including, but not limited to, reactive ion etching (RIE), plasma etching, inductive coupled plasma RIE (ICP-RIE), ion milling, etc. This step also includes depositing metal contacts using common metal deposition techniques, such as electron beam evaporation or thermal evaporation.

Block 908 represents the results of the process, namely, the resulting LD epitaxial structures according to the present invention.

### NOMENCLATURE

The terms “Group-III nitrides” or “III-nitrides” or “nitrides” as used herein refer to any alloy composition of the (Ga, Al, In, B) N semiconductors having the formula GaₙAlₓIn_{y}B_{z}N where:

$$0 \leq n \leq 1 , 0 \leq x \leq 1 , 0 \leq y \underline{<} 1 , 0 \leq z \leq 1 , and n + x + y + z = 1$$

These terms as used herein are intended to be broadly construed to include respective nitrides of the single species, Ga, Al, In and B, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (Ga, Al, In, B)N component species are present, all possible compositions, including stoichiometric proportions as well as off-stoichiometric proportions (with respect to the relative mole fractions present of each of the (Ga, Al, In, B)N component species that are present in the composition), can be employed within the broad scope of this invention. Further, compositions and materials within the scope of the invention may further include quantities of dopants and/or other impurity materials and/or other inclusional materials.

### REFERENCES

The following publications are incorporated by reference herein:
[1] T. Nakamura and K. Motoki, “GaN Substrate Technologies for Optical Devices,” Proceedings of the IEEE, vol. 101, no. 10, pp. 2221-2228, 2013.
[2] H. Yoshida, Y. Yamashita, M. Kuwabara and H. Kan, “A 342-nm ultraviolet AlGaN multiple-quantum-well laser diode,” Nature Photonics, vol. 2, pp. 551-554, 2008.
[3] S. Lee, D. Koleske, K.-. Cross, J. Floro and K. Waldrip, “In situ measurements of the critical thickness for strain relaxation in AlGaN/GaN heterostructures,” Appl. Phys. Lett, vol. 85, p. 6164, 2004.
[4] K. Nagata, Phys. Status Solidi C, vol. 8, no. 5, 2011.
[5] S. Huang, Y. Zhang, B. Leung, G. Yuan, G. Wang, H. Jiang, Y. Fan, Q. Sun, W. Jianfeng, K. Xu and J. Han, “Mechanical Properties of Nanoporous GaN and Its Application for Separation and Transfer of GaN Thin Films,” ACS Appl. Mater. Interfaces, vol. 5, no. 21, pp. 11074-11079, 2013.

What claimed is:

1. A device, comprising:
a III-nitride laser diode with an emission wavelength between 300 nm and 370 nm, grown on or above a nano-porous AlₐGa₁₋ₐN layer, where 0<a≤1, and the nano-porous AlₐGa₁₋ₐN layer is grown on or above a III-nitride substrate.

2. The device of claim 1, wherein the nano-porous AlₐGa₁₋ₐN layer has a bandgap energy equal to a photon energy of the emission wavelength of the III-nitride laser diode.

3. The device of claim 1, wherein the nano-porous AlₐGa₁₋ₐN layer is n-type and has an Si or Ge dopant concentration in a range from 10¹⁷ cm⁻³ to 10²⁰ cm⁻³.

4. The device of claim 1, wherein the III-nitride laser diode includes a III-nitride-based light-emitting active region comprised of AlₓGa₁₋ₓN grown on or above the nano-porous AlₐGa₁₋ₐN layer, where 0≤x≤1 and a>x.

5. The device of claim 4, wherein the III-nitride laser diode includes an n-type Al_{b}Ga_{1-b}N layer grown on or above the nano-porous AlₐGa₁₋ₐN layer, before the III-nitride-based light-emitting active region comprised of AlₓGa₁₋ₓN is grown, where 0<b≤1, b>a, and b>x, and the n-type Al_{b}Ga_{1-b}N layer comprises a separate confinement heterostructure (SCH) layer or waveguiding layer.

6. The device of claim 5, wherein the III-nitride laser diode includes a p-type Al_{c}Ga_{1-c}N layer grown on or above the III-nitride-based light-emitting active region comprised of AlₓGa₁₋ₓN, where 0<c≤1 and c>x, and the p-type Al_{c}Ga_{1-c}N layer comprises a separate confinement heterostructure (SCH) layer or waveguiding layer.

7. The device of claim 6, wherein the p-type Al_{c}Ga_{1-c}N layer has a bandgap energy equal to a photon energy of the emission wavelength of the III-nitride laser diode.

8. The device of claim 6, wherein the p-type Al_{c}Ga_{1-c}N layer has an Mg dopant concentration in a range from 10¹⁷ cm⁻³ to 10²⁰ cm⁻³.

9. The device of claim 6, wherein the p-type Al_{c}Ga_{1-c}N layer contains at least one superlattice (SL) having at least two alternating layers of AlₓGa₁₋ₓN and Al_{y}Ga_{1-y}N where 0<x≤1 and 0<y≤1.

10. The device of claim 9, wherein the p-type Al_{c}Ga_{1-c}N layer has a continuously varying composition between the at least two alternating layers of AlₓGa₁₋ₓN and Al_{y}Ga_{1-y}N.

11. The device of claim 6, wherein the p-type Al_{c}Ga_{1-c}N layer is three-dimensional (3D) polarization doped.

12. The device of claim 7, wherein a p-AlₐGa₁₋ₐN cladding layer is grown on or above the p-type Al_{c}Ga_{1-c}N layer, where 0<d≤1 and d>c.

13. The device of claim 12, wherein the p-AlₐGa₁₋ₐN cladding layer is a compositionally graded structure, where d varies from d1 to d2 and d1>d2.

14. The device of claim 12, wherein the p-AlₐGa₁₋ₐN cladding layer has a refractive index less than the p-type Al_{c}Ga_{1-c}N layer and the III-nitride-based light-emitting active region.

15. The device of claim 12, wherein the p-AlₐGa₁₋ₐN cladding layer is comprised of one or more short-period superlattice (SPSL) structures.

16. The device of claim 12, wherein the III-nitride laser diode includes a partially or fully transparent oxide layer on or above the p-AlₐGa₁₋ₐN cladding layer or the p-type AlcGai-&N layer.

17. The device of claim 16, wherein the partially or fully transparent oxide layer is indium tin oxide (ITO), zinc oxide (ZnO), gallium oxide (GaOₓ), indium zinc oxide (IZO), silicon diode (SiO₂) or another oxide layer.

18. A method, comprising:
fabricating a III-nitride laser diode with an emission wavelength between 300 nm and 370 nm, grown on or above a nano-porous AlₐGa₁₋ₐN layer, where 0<a≤1, and the nano-porous AlₐGa₁₋ₐN layer is grown on or above a III-nitride substrate.
